(19) United States
(12) Patent Application Publication
(10) Pub. No.: US 2016/0260876 A1
(43) Pub. Date: Sep. 8, 2016

(54) LED LIGHT SOURCE AND MANUFACTURING METHOD THEREOF

(71) Applicants: Ming SUN, Shanghai (CN); Jian DAI, Shanghai (CN); SHANGHAI OPPELLIGHTING CO., LTD., Shanghai (CN)

(72) Inventors: Ming Sun, Shanghai (CN); Wen-Jung Chuang, Suzhou City (CN); Xing-Bao Chen, Shanghai (CN); Jian Dai, Shanghai (CN)

(73) Assignee: Shanghai Oppellighting Co., Ltd., Shanghai (CN)

(21) Appl. No.: 14/395,094

(22) PCT Filed: Aug. 15, 2014
(86) PCT No.: PCT/CN2014/084504

§ 371 Date: Oct. 17, 2014

(30) Foreign Application Priority Data
Nov. 18, 2013 (CN) 201310576070.7

(51) Int. Cl. H01L 33/62; H01L 25/075; H01L 33/64; H01L 33/50; H01L 33/56

(52) U.S. Cl. CPC H01L 33/62; H01L 33/502; H01L 33/56; H01L 33/641; H01L 25/0753; H01L 2933/0041; H01L 2933/005; H01L 2933/0066; H01L 2933/0075

(57) ABSTRACT

The present invention is related to a LED light source and its manufacturing method. It is related to the LED technology field. The LED light source includes a glass case, LED chips sealed inside the glass case and the transparent substrate carrying the LED chips. The manufacturing method of the present invention is simple and easy.

### BACKGROUND OF THE INVENTION

1. Field of the Invention

The present invention relates to a LED light source and its manufacturing method, especially relates to a manufacturing method of a LED light source.

2. Descriptions of the Related Art

LED light source is the light source exerting the light emitting diode as the luminant The light emitting diode was invented at 60's in 20 century and served as the indication light for the electronics such as the radio for passing decades. Because the LED has the advantages of high efficiency and long life time, it can be operated over one hundred thousand hours which is one hundred times longer than the incandescent light can. Hence, within the five years, the LED must become the mainstream of the lightening.

In the aspect of luminous efficiency, the efficiency of the LED has been greatly improved after decade's development. The efficiency of the incandescent light or the tungsten light is around 12 lumen/W to 24 lumen/W. The efficiency of the fluorescent light is around 50 lumen/W to 70 lumen/W. The efficiency of the sodium light is around 90 lumen/W to 140 lumen/W. Most of the power consumption turns into heat loss. The efficiency of the modified LED light can be ranging from 50 lumen/W to 200 lumen/W or even higher. Also, the LED light has more advantages such as good monochromaticity and narrow optical spectrum and can directly emit visual lights with different colors without filtering. Due to the great efforts and researches done worldwide, the luminous efficiency of the LED must soon be impressively improved.

In the aspect of power saving, the single tube power of the LED is ranging from 0.03 W to 0.06 W via DC driving. The single tube driving voltage is ranging from 1.5 V to 3.5 V and the current is ranging from 15 mA to 18 mA. The LED has rapid response time and can be operated in high frequency. Under the same lightening condition and taking the LED light as the baseline, the power consumption of the incandescent light is ten thousand times and the power consumption of the fluorescent light is two times. According to the estimation form Japan's research, six thousand million liter of the petroleum can be saved each year if half of the incandescent lights and the fluorescent lights are replaced via the LED lights having only half times of power consumption of the fluorescent light. Take the lights installed on the bridges, the power consumption of LED light is only 8 W while the power consumption of the incandescent light may be over 40 W and additionally, the LED lights may provide colorful lightening.

Hence, many researches are done for the LED light source and/or for the LED mechanical design to improve the performance of the LED light so that the LED light source can easily and conveniently replace the traditional light source.

### SUMMARY OF THE INVENTION

According to the deficiencies in the prior art, the present invention provides a novel LED light source and its manufacturing method to re-design the LED light source so that the process of manufacturing the LED light source can be simplified.

The LED light source of the present invention is disclosed as follow.

A LED light source including a glass case, at least two LED chips, a glass substrate, at least one electrode and at least one lead. The LED chips are installed on the glass substrate and sealed via the glass case. An AlN layer is sputtered on a surface of the glass substrate serving as a heat dissipation layer. An ITO circuit layer is sputtered to electrically couple the LED chips to other the LED chips and the leads. The LED chips are installed on the ITO circuit layer of the glass substrate so that the LED chips electrically couple to other the LED chips and the leads via the ITO circuit layer.

The present invention discloses a LED light source, wherein a P-electrode and an N-electrode of each the LED chip are directly laid on the ITO circuit layer to electrically couple.

The present invention discloses a LED light source, wherein the P-electrode and the N-electrode are electrically coupled to the ITO circuit layer via a transparent conductive gel.

The present invention discloses a LED light source, wherein the P-electrode and the N-electrode are electrically coupled to the ITO circuit layer via a solder.

The present invention discloses a LED light source, wherein the surface of the glass case is covered via a fluorescent powder layer and a volume V of the glass case is larger than 0.1 cm³ and less than 15 cm³.

The present invention discloses a LED light source, wherein the glass case further includes an inlet/outlet opening for vacuuming the glass case or injecting a He/N mixture gas.

The present invention discloses a LED light source, wherein the fluorescent powder layer is covered a surface of the glass case uniformly.

The present invention also discloses a manufacturing method to produce the LED light source and the method includes the follow steps: select the glass substrate and sputter the AlN layer on the glass substrate; directly sputter the ITO circuit layer on the AlN layer to electrically couple the chips and the leads, wherein different the ITO circuit layers are not electrically coupled; lay the P-electrode and the N-electrode of each the LED chip on the ITO circuit layer to electrically coupled; electrically couple different ITO circuit layers via the LED chip; cover the fluorescent powder layer on surfaces of the LED chip and the glass substrate; and Lead the leads out from the glass case which is melt with the glass substrate having the LED chips.

The present invention discloses a method, wherein the glass substrate is spin sputtered to form the ITO circuit layer. The spin frequency is ranging from 40 Hz to 60 Hz and Sn-doping content is ranging from 7% to 12%. The thickness of the ITO circuit layer is ranging from 20 nm to 200 nm and oxygen flux is ranging 2 sccm to 7 sccm.

The present invention discloses a method, wherein Sn-doping content is ranging from 9% to 11%. The thickness of the ITO circuit layer is ranging from 140 nm to 180 nm and oxygen flux is ranging 3 sccm to 5 sccm.

The present invention discloses a method, wherein the P-electrode and the N-electrode are electrically coupled to the ITO circuit layer via the transparent conductive gel and the solder.

The present invention discloses a method, wherein the glass case further includes the inlet/outlet opening and via the inlet/outlet opening to vacuum the glass case or to inject the He/N mixture gas after sealing an end of the leads of the glass case.

The present invention discloses a method, wherein the He/N mixture gas is prepared via mixing He:N from 5:1 to 2:1 in volume and the pressure of the glass case ranging from 0.05 to 0.15 MPa at room temperature.

The present invention discloses a method, wherein sputter the fluorescent powder layer on an area except the P/N electrodes before cutting the LED chip.

The present invention discloses a method, wherein cover said fluorescent powder layer on said surface of said glass case after cooling said sealed glass case.

According to the present invention, the mechanical configuration and the manufacturing method of the LED light source can be re-design to simplified the process. Meanwhile, the LED light source of the present invention has lower power consumption and longer operation time.

### BRIEF DESCRIPTION OF THE DRAWINGS

FIG. 1 illustrates a LED package having LED chips, a transparent substrate covering a uniform fluorescent powder layer.

FIG. 2 illustrates a LED package having LED chips covering a uniform fluorescent powder layer.

FIG. 3 illustrates a LED chip is directly laid on the ITO circuit layer.

FIG. 4 illustrates a LED light source having a melt-sealing end nearby the leads.

FIG. 5 illustrates a LED light source having a melt-sealing end nearby the leads covering a fluorescent powder layer.

FIG. 6 illustrates a LED light source having an inlet/outlet opening.

FIG. 7 illustrates a LED light source having an inlet/outlet opening on the surface of the glass case covering a fluorescent powder layer.

### EXPLANATIONS OF LETTERS OR NUMERALS

1 LED chip

1′ LED chip covering a fluorescent powder layer

2 glass substrate

2′ glass substrate covering a fluorescent powder layer

3 glass case

3′ glass case covering a fluorescent powder layer

4 melt-sealing end covering a fluorescent powder layer

5 electrode

6 lead

7 inlet/outlet opening

7′ inlet/outlet opening covering a fluorescent powder layer

8 glass substrate covering a fluorescent powder layer

8′ glass substrate without a fluorescent powder layer

9 chip covering a fluorescent powder layer

9′ chip without a fluorescent powder layer

10 ITO circuit layer sputtered on the substrate

### DESCRIPTION OF THE PREFERRED EMBODIMENT

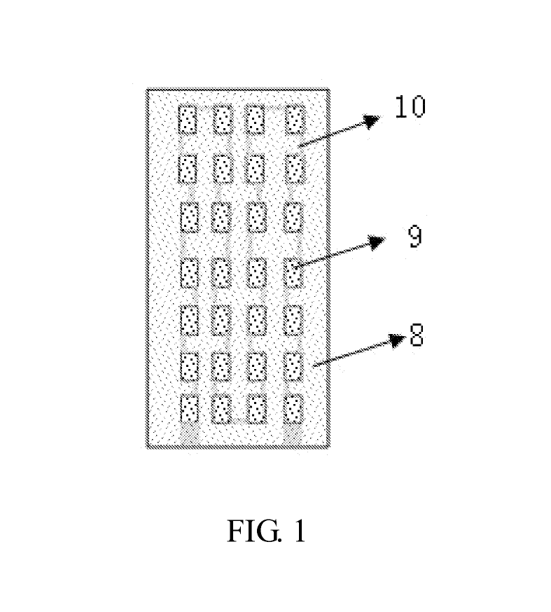

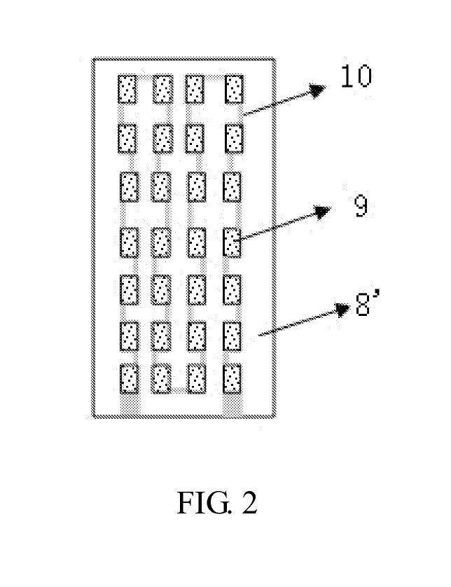

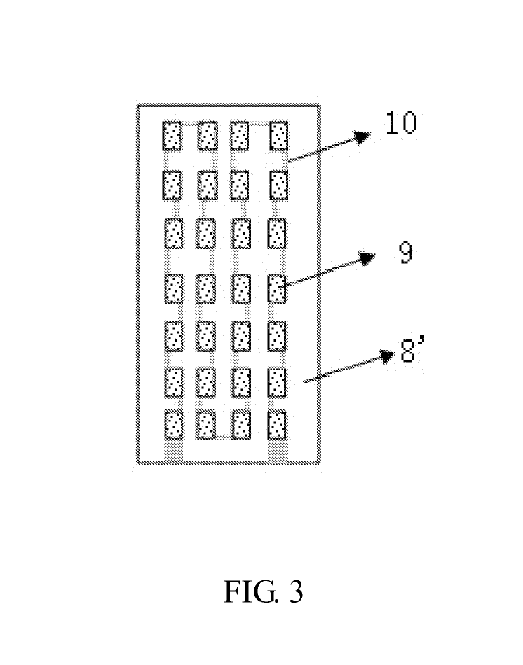

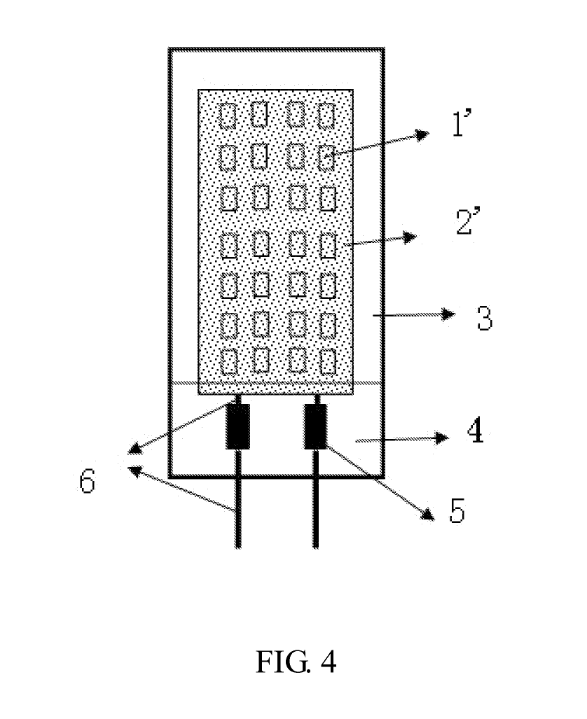

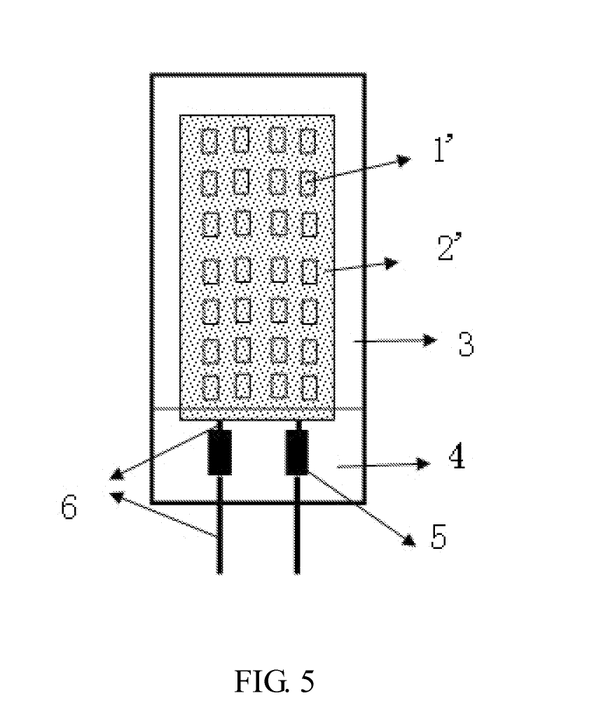

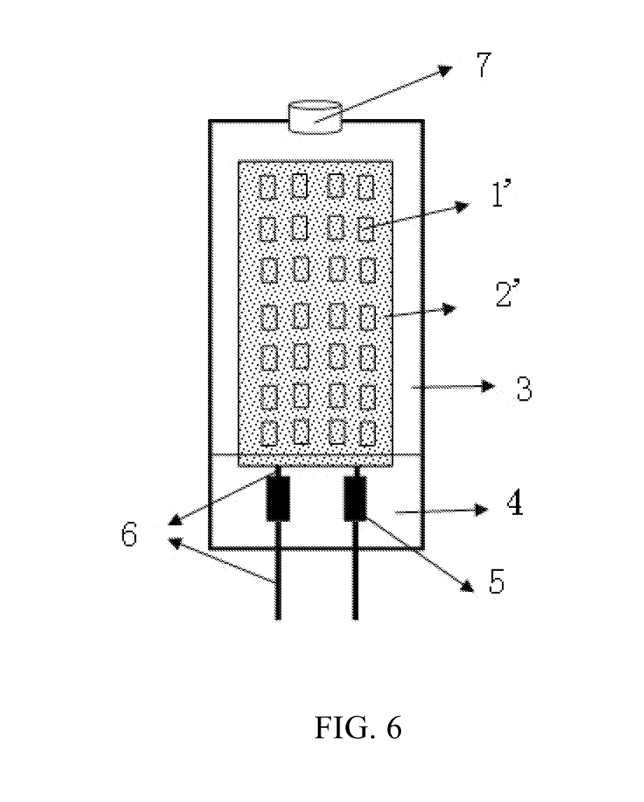

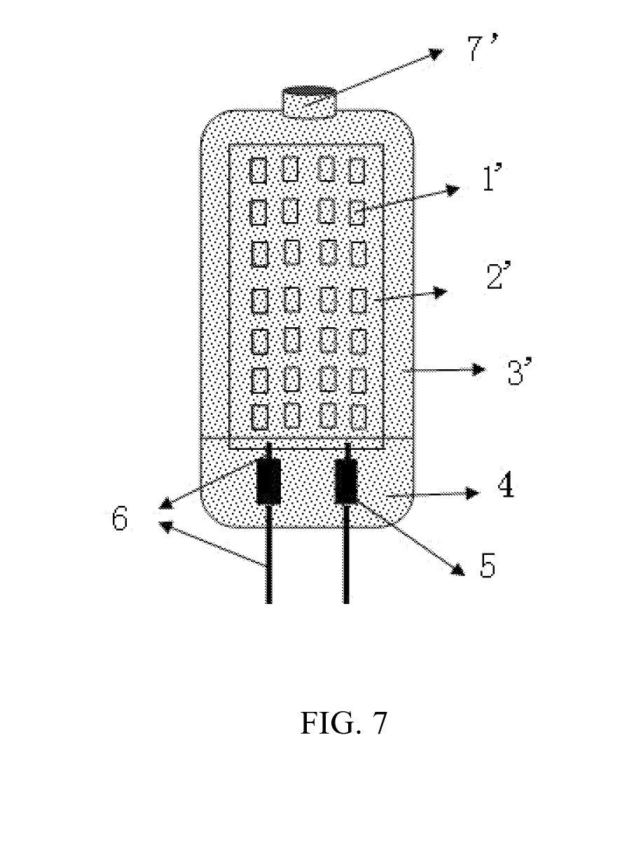

Referring to the FIG. 1 to FIG. 7, the present invention provides a LED light source and its manufacturing method. The LED light source of the present invention includes a glass case 3, at least two LED chips 1, a glass substrate 2, at least one electrode 5 and at least one lead 6. The LED chips 1 are installed on the glass substrate 2 and sealed via the glass case 3. An AlN layer is sputtered on a surface of the glass substrate 2 serving as a heat dissipation layer. Due to the transparency and electrical conductivity of ITO, an ITO circuit layer is sputtered to electrically couple the LED chips 1 to other the LED chips 1 and the leads 6. The LED chips 1 are installed on the ITO circuit layer of the glass substrate 2 so that the LED chips 1 electrically couple to other the LED chips 1 and the leads 6 via the ITO circuit layer. The LED chips 1 on the glass substrate 2 and the glass substrate 2 itself are all sealed inside the glass case 3. The substrate wires, which electrically couple the LED chips 1 and the external power supply, are electrically coupled to the electrodes 5. The conductive wires of the electrodes 5 are electrically coupled to the power supply. The glass substrate 2 having the LED chips 1 is sealed inside the glass case 3. The lead end of the glass substrate 2, the substrate wires, the electrodes and the conductive wires of the electrodes are sealed via melting in one end of the glass case 3. The conductive wires of the electrodes 5 extrude from the melt-sealing end of the glass case 3.

The P electrode and N electrode of the LED chip 1 are directly laid on the corresponding ITO circuit layer to electrical coupling. More precisely, the P electrode and N electrode of the LED chip are installed and electrically coupled via the transparent conductive gel and ITO. Or, the P electrode and N electrode of the LED chip can be installed and electrically coupled via a solder.

The LED chips 1 of the LED light source are installed on ITO so that the LED chips 1 and the power supply can be directly electrically coupled. Hence, the LED chips 1 are installed on the glass substrate 2 directly and are covered via a fluorescent powder layer on the surfaces. The surface of the glass case 3 can be covered via multiple layers of the fluorescent powder layers exerted for exciting the light emitting diode during operation. Meanwhile, parts of the fluorescent powder layer on the LED chip 1 might be deactivated while melting the glass case 3 at the elevated temperature. So, more than one layer of the fluorescent powder layer covered on the glass case 3 can effectively prevent the blue light leakage due to the incomplete excitation of the LED chip. The glass case 3 is better has the volume ranging from 0.1 cm³ to 15 cm³ in order to be suitable for all kinds of lighting devices.

Because the P and N electrodes of the LED chip 1 of the present invention are directly laid on the ITO of the substrate, it is impossible to cover the fluorescent powder layer onto the ends of P and N electrodes of the LED chips 1. Hence, the ends of P and N electrodes of the LED chips 1 can be sputtered the fluorescent powder layer before cutting the LED chips 1.

In order to improve the heat dissipation ability of the LED chip 1 during operation, the glass case 3 further includes an inlet/outlet opening 7 so that the components, especially ITO, inside the glass case 3 would not be affected via the surroundings. Via the input/output opening, the glass case 3 can be vacuumed or injected the He/N mixture gas. After injection, seal the inlet/outlet opening 7. Because the ITO absorbs the moisture easily, the ITO would rot after absorbing the moisture and carbon dioxide from the atmosphere. After installing the LED chips 1 onto the glass substrate 2 having the ITO circuit layer, the sealed glass case 3 can provide an isolation environment from the surroundings. On the other hand, the glass case 3 can be injected mixture gas to enhance the ability of heat dissipation so that the operation temperature of the LED light source can be reduced. The mixture gas mentioned above is the He/N mixture gas prepared via mixing He:N from 5:1 to 2:1 in volume and the pressure of the glass case ranging from 0.05 to 0.15 MPa at room temperature.

If no fluorescent powder layer exerted on the surface of the LED chips 1 as installed onto the glass substrate 2, the fluorescent powder layer may be uniformly covered on the surface of the glass case 3 as sealing so that the lights from the LED chips 1 can be excited. Moreover, as the fluorescent powder layer is covered on the surface of the glass case 3 and avoids direct contact with the LED chips 1, the damage from heat generated via the LED chips 1 so that the fluorescent powder layer would not be aged. The fluorescent powder layer is covered onto the glass case 3 after sealing and cooling down.

The present invention also discloses a manufacturing method to produce the LED light source and the method includes the follow steps. Sputter the AlN layer on the glass substrate and spin sputter the ITP circuit layer in the spin frequency ranging from 40 Hz to 60 Hz and Sn-doping content ranging from 7% to 12%. The thickness of the ITO circuit layer is ranging from 20 nm to 200 nm and oxygen flux is ranging 2 sccm to 7 sccm. More precisely, Sn-doping content is better ranging from 9% to 11%. The thickness of the ITO circuit layer is better ranging from 140 nm to 180 nm and oxygen flux is better ranging 3 sccm to 5 sccm. In the present invention, no annealing is required after ITO sputtering. In order to provide a uniform sputtered ITO, an optimized transparent ability and an optimized resistivity, the spin frequency ranging from 40 Hz to 60 Hz during sputtering is recommended.

Besides, the AlN layer is sputtered onto the glass substrate 2 before sputtering the ITO circuit layer. Precisely, the ITO circuit layer of the present invention is sputtered onto the AlN layer. Due to the existence of the AlN layer, the operation temperature of ITO sputtering cannot be over 300° C. or the transparency of the AlN layer would be damaged. Traditionally, in order to modify the roughness and the resistivity of the ITO surface and to increase the transparency of the ITO, an annealing procedure is adopted. Based on the results of the research, to get better photoelectrical performance of the ITO, the higher annealing temperature is required, especially up to 450° C. However, because the ITO circuit layer of the present invention covers the AlN layer, it is different from the traditional ITO directly covering the glass substrate 2. Hence, the ITO circuit layer is formed via spin sputtering to improve the photoelectrical performance of the ITO and that is the reason why no more annealing procedure is required in the present invention. Meanwhile, the risk of damaging the Sn and In of the ITO during annealing can be eliminated. The method of the present invention can effectively control the stability of the photoelectrical performance of the ITO.

It is found that parts of In2O3 and SnO2 would be decomposed into suboxides which affect the transparency, resistivity and film-forming ability of the ITO circuit layer because the suboxides have lower drift mobility and various film-forming rates in different areas. These suboxides would make the ITO rough or shadowed. Higher oxygen flux would cause high resistivity; lower oxygen flux would cause poor transparency and film having shadows and roughness. Nevertheless, the oxygen quantities required for reaching the optimized resistivity, transparency and roughness are almost the same but the directions of the oxygen fluxes are different. Consequently, in order to optimize the resistivity, transparency and roughness at the same time, the oxygen flux must be adjust to an optimized parameter so that the better resistivity, transparency and roughness of the ITO can be achieved. According to the experiment results, to optimize the resistivity, transparency and morphology of the ITO, the oxygen flux is ranging from 2 sccm to 7 sccm, wherein the oxygen flux is better ranging from 3 sccm to 5 sccm.

Select and wash the glass substrate via alcohol. Sputter the AlN layer onto the surface of the glass substrate. Spin sputter the ITO circuit layer onto the AlN layer to electrically couple the LED chip to other LED chips and the leads as well. Cover the photoresist to shelter the area not to be sputtered so that the different ITO circuit layers would not electrically couple to each other. The formation of ITO is under the following conditions: the spin frequency of the glass substrate is 50 Hz, Sn-doping content is around 10%, the thickness of the ITO circuit layer is 160 nm and oxygen flux is 5 sccm. Remove the photoresist after spin sputtering the ITO. Install the P electrode of one LED chip and the N electrode of another LED chip in two ends of the ITO circuit layer respectively. The LED chips 1 except the P and N electrodes are first sputtered the fluorescent powder layer and then are cut. Different ITO circuit layers are electrically coupled via these LED chips. Cover the fluorescent powder layer on the surfaces of the installed LED chips and the glass substrate. Melt one end of the glass case 3 and the glass substrate 2 having all the LED chips together and lead out the lead from the melted-sealing end. Vacuum and inject the He/N mixture gas via the inlet/outlet opening in another end of the glass case 3. The He/N mixture gas is prepared via mixing He:N from 5:1 to 2:1 in volume and the pressure of the glass case ranging from 0.05 to 0.15 MPa at room temperature. Seal the glass case 3 via melting the inlet/outlet opening. Cover the fluorescent powder layer uniformly on the surface of the glass case 3.

The above embodiments merely give the detailed technical contents of the present invention and inventive features thereof, and are not to limit the covered range of the present invention. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A LED light source including a glass case, at least two LED chips, a glass substrate, at least one electrode and at least one lead, wherein said LED chips are installed on said glass substrate and sealed via said glass case; an AlN layer is sputtered on a surface of said glass substrate serving as a heat dissipation layer; an ITO circuit layer is sputtered to electrically couple said LED chips to other said LED chips and said leads; said LED chips are installed on said ITO circuit layer of said glass substrate so that said LED chips electrically couple to other said LED chips and said leads via said ITO circuit layer.

2. The LED light source of claim 1, wherein a P-electrode and an N-electrode of each said LED chip are directly laid on said ITO circuit layer to electrically couple.

3. The LED light source of claim 2, wherein said P-electrode and said N-electrode are electrically coupled to said ITO circuit layer via a transparent conductive gel.

4. The LED light source of claim 2, wherein said P-electrode and said N-electrode are electrically coupled to said ITO circuit layer via a solder.

5. The LED light source of claim 1, wherein said surface of said glass case is covered via a fluorescent powder layer and a volume V of said glass case is larger than 0.1 cm³ and less than 15 cm³.

6. The LED light source of claim 1, wherein said glass case further includes an inlet/outlet opening for vacuuming said glass case or injecting a He/N mixture gas.

7. The LED light source of claim 1, wherein a fluorescent powder layer is covered a surface of said glass case uniformly.

8. A manufacturing method to produce said LED light source in claim 1 including following steps:
select said glass substrate and sputter said AlN layer on said glass substrate,
directly sputter said ITO circuit layer on said AlN layer to electrically couple said chips and said leads, wherein different said ITO circuit layers are not electrically coupled,
lay said P-electrode and said N-electrode of each said LED chip on said ITO circuit layer to electrically coupled,
electrically couple different ITO circuit layers via said LED chip,
cover said fluorescent powder layer on surfaces of said LED chip and said glass substrate, and
lead said leads out from said glass case which is melt with said glass substrate having said LED chips.

9. The manufacturing method of claim 8, wherein said glass substrate is spin sputtered to form said ITO circuit layer; spin frequency is ranging from 40 Hz to 60 Hz; Sn-doping content is ranging from 7% to 12%; thickness of said ITO circuit layer is ranging from 20 nm to 200 nm and oxygen flux is ranging 2 sccm to 7 sccm.

10. The manufacturing method of claim 9, wherein Sn-doping content is ranging from 9% to 11%; thickness of said ITO circuit layer is ranging from 140 nm to 180 nm and oxygen flux is ranging 3 sccm to 5 sccm.

11. The manufacturing method of claim 8, wherein said P-electrode and said N-electrode are electrically coupled to said ITO circuit layer via said transparent conductive gel and said solder.

12. The manufacturing method of claim 8, wherein said glass case further includes said inlet/outlet opening and via said inlet/outlet opening to vacuum said glass case or to inject said He/N mixture gas after sealing an end of said leads of said glass case.

13. The manufacturing method of claim 8, wherein said He/N mixture gas is prepared via mixing He:N from 5:1 to 2:1 in volume and a pressure of said glass case ranging from 0.05 to 0.15 MPa at room temperature.

14. The manufacturing method of claim 8, wherein sputter said fluorescent powder layer on an area except said P/N electrodes before cutting said LED chip.

15. The manufacturing method of claim 8, wherein cover said fluorescent powder layer on said surface of said glass case after cooling said sealed glass case.
